(19) United States
(12) Patent Application Publication
(10) Pub. No.: US 2024/0392441 A1
(43) Pub. Date: Nov. 28, 2024

(54) CVD REACTOR WITH A SUPPORTING RING, AND SUPPORTING RING FOR A SUBSTRATE

(71) Applicant: AIXTRON SE, Herzogenrath (DE)

(72) Inventors: Jared Lee HOLZWARTH, Aachen (DE); Marcel KOLLBERG, Würselen (DE); Merim MUKINOVIC, Würselen (DE); Stephan STRAUCH, Stolberg (DE)

(21) Appl. No.: 18/699,006

(22) PCT Filed: Oct. 6, 2022
(86) PCT No.: PCT/EP2022/077767

§ 371 Date: Apr. 5, 2024

(30) Foreign Application Priority Data
Oct. 7, 2021 (DE) 10 2021 126 019.1

(51) Int. Cl. C23C 16/458; C23C 16/32

(52) U.S. Cl. CPC C23C 16/4585; C23C 16/325; C23C 16/4586

(57) ABSTRACT

A supporting ring is arranged in a CVD reactor and is part of a bearing arrangement which is intended for the mounting of a substrate. The bearing arrangement is arranged above a susceptor and is supplied with heat by the susceptor. The heat is transferred from the susceptor to a radially outer region or to a radially inner region of the supporting ring via an annular web of the supporting ring.

### RELATED APPLICATIONS

This application is a National Stage under 35 USC 371 of and claims priority to International Application No. PCT/EP2022/077767, filed 6 Oct. 2022, which claims the priority benefit of DE Application No. 10 2021 126 019.1, filed 7 Oct. 2021.

### FIELD OF THE INVENTION

The invention relates to a supporting ring for use in a CVD reactor, with a radially inner region, which has a lower face for the seating on a supporting flank of a substrate holder, and has a seating face that is located opposite the lower face, which adjoins a contact surface, with a radially outer region, which has an upper face and a lower face that is located opposite the upper face, and adjoins an outer wall extending along a cylindrical shell surface, wherein the outer wall is formed by an annular web forming an inner wall located opposite the outer wall, wherein the inner wall extending along a hollow cylinder inner surface adjoins the lower face of the radially inner region extending radially within the inner wall.

The invention also relates to an arrangement comprising such a supporting ring and a substrate holder, and also a CVD reactor, which has one or a plurality of such arrangements.

### BACKGROUND

US 2010/0071624 A1 discloses a CVD reactor with a susceptor. The susceptor has an upper face on which a substrate that is to be coated can be placed. The edge of the substrate projects beyond a peripheral recess of the susceptor, in which a radially inner region of a supporting ring engages. A radially outer region of the supporting ring projects over an annular web.

DE 10 2013 012 082 A1 describes a CVD reactor with a susceptor that is heated from the lower face, and supports a substrate holder on which a substrate can be placed. In one example of embodiment, a supporting ring rests on a step of the substrate holder. The radially inward-facing surface of the supporting ring widens from top to bottom in the manner of a truncated cone inner surface. The inward-facing surface is also stepped, so that a cross-sectional area through the supporting ring has a T-shaped configuration.

DE 102 32 731 A1 discloses a supporting ring, which also has a T-shaped cross-sectional configuration, wherein the surface of the supporting ring facing inwards towards the substrate holder also runs on a truncated conical shell surface.

DE 10 2020 117 645 A1 discloses a supporting ring for use in a CVD reactor that has a Z-shaped cross-section.

US 2016/0172165 A1 discloses a susceptor that forms a step along its edge. A supporting ring lies on this step, which ring supports the edge of a substrate on an inward-facing supporting shoulder. In the radially outer region, a downward-facing rib of the supporting ring engages in an annular recess in the susceptor. The vertical height of the rib is less than the vertical depth of the recess, so that the lower end face of the rib is removed from the step surface.

DE 10 2017 101 648 A1 and DE 101 35 151 A1 each disclose a CVD reactor in which a substrate to be coated rests on a substrate holder that supports a supporting ring with which the substrate can be transported.

In a CVD reactor, as is of known art, for example, in DE 10 2018 113 400 A1, a susceptor arrangement is heated from below with a heating device. A generic CVD reactor is used for the deposition of silicon or silicon carbide. The deposition process requires process temperatures of 1,300° C. to 1,600° C. The susceptor arrangement has a base plate that is heated by the heating device. The heat generated by the heating device flows through the base plate into a substrate holder that supports the substrate. A radially inner region of a supporting ring is supported on a supporting flank of the substrate holder, with which the substrate can be transported during loading or unloading of the CVD reactor, for which purpose the supporting ring has a radially outer region that can be gripped from below by a gripper. The supporting ring is heated by way of the heat fed into the substrate holder, and by way of the heat transferred to the supporting ring via the supporting flank. The supporting ring arranged on the floor of a process chamber transfers heat, as do the substrates arranged there, to a cooler process chamber ceiling. The supporting ring is therefore located within a temperature gradient between the base plate and the process chamber ceiling. Deformations or other inaccuracies in the region of the interfaces between the supporting ring and the substrate holder, or between the substrate holder and the base plate, can influence the heat flow. As a result, the temperature of the transport ring is subject to fluctuations.

### SUMMARY OF THE INVENTION

The invention is based on the object of specifying measures with which these temperature fluctuations can be reduced.

The object is achieved by the invention as specified in the claims. The subsidiary claims represent not only advantageous developments of the invention specified in the independent claims, but also independent achievements of the object.

In accordance with a first aspect of the invention, a supporting ring is proposed, which has a T-shaped cross-section. The two T-legs form a radially inner region and a radially outer region. The T-web forms an annular web, by way of which the heat is transported from the base plate to the radially inner, or radially outer, ring. The radially inner region has a lower face, with which the supporting ring can rest on a supporting flank of a substrate holder. Located opposite the lower face, which extends in a plane, is a seating face, which also extends in a plane, and on which an edge of a substrate that is to be coated can rest during transport into or out of the process chamber. The seating face can be part of a recess that is formed by a contact surface. The contact surface can extend along the inner surface of a hollow cylinder. The radially outer region of the supporting ring has a lower face extending in one plane, which can be gripped from below by a fork, or a gripper arm, so as to lift the supporting ring from the substrate holder, and thus transport the substrate. Opposite the lower face of the radially outer region is located an upper face. The lower face of the radially inner region adjoins an inner wall of the annular web, which extends along a hollow cylinder inner surface. An outer wall of the annular web, which extends along a cylindrical shell surface, adjoins the lower face of the radially outer region. The lower face of the radially outer region and the lower face of the radially inner region can run in offset planes. Thus, for example, the lower face of the radially outer region can be at a greater distance from a lower edge of the annular web, than the lower face of the radially inner region is from the lower edge of the annular web. It can also be envisaged that the inner wall is widened in a region that adjoins the lower edge of the annular web, forming an incline or a chamfer. This makes it easier to place the ring on the substrate holder. In a further development, the supporting ring is made of silicon carbide. A further aspect of the invention relates to the contact surface; this can be a hollow cylindrical inner surface, and can run radially inside the outer wall and radially outside the inner wall of the annular web.

The supporting ring can be a solid annular body that has a constant cross-section over its entire periphery. The height of the annular web can be greater than the radial extent of the radially inner region, or the radially outer region. The material thickness of the annular web can be greater than the material thickness of the radially inner region. It can be less than the material thickness of the radially outer region. The material thickness of the annular web can be less than, and in particular less than half, the height of the annular web, wherein the height of the annular web can be understood to be the distance between the lower edge of the annular web and one of the two lower faces of the radially outer region, or the radially lower region. If the two distances differ from each other, the height of the annular web can be understood to be the lesser of the two distances. The free end faces of the radially outer and inner regions, as well as the lower edge of the annular web, can have rounded edges.

The T-shape of the inventive supporting ring gives it increased torsional rigidity compared to a supporting ring previously used in the deposition of SiC. Furthermore, it is advantageous if the diameter of the contact surface, which serves to center the substrate on the upper face of the substrate holder, corresponds approximately to the diameter of the inner wall of the annular web. The diameter of the inner wall of the annular web is only slightly greater than the diameter of the peripheral wall of the substrate holder. The dimensioning of the diameter of the contact surface in accordance with the invention thus results in the bearing surface for the mounting of the substrate, bounded by the contact surface, corresponding approximately to the layout of the substrate holder. In the course of the coating of the substrate, the outer edge of the substrate is therefore approximately flush with the peripheral edge of the substrate holder. The substrate holder therefore has approximately the same diameter as the substrate. In a preferred configuration of the invention, substrates with a nominal diameter of 150 mm are coated. The mounting surface bounded by the contact surface then preferably has a diameter of approximately 151 mm, whereas the diameter of the substrate holder can be 150 mm. The inner diameter of the inner wall of the annular web only needs to be half a millimeter greater than the diameter of the substrate holder in order to place the transport ring automatically on the substrate holder, and to remove it again from the latter. It also proves to be particularly advantageous if the radial extent of the radially inner region is as small as possible, and in particular corresponds approximately to the material thickness of the radially inner region, which is preferably 2 mm. The material thickness of the radially outer region preferably has the same value. However, the radial extent of the radially outer region can be greater than the radial extent of the radially inner region. The substrate holder can rest directly on an upper face of a susceptor. However, it can also be supported by a gas cushion, which is built up between the upper face of the susceptor and the lower face of the substrate holder by feeding in a gas.

The invention also relates to a bearing arrangement for the mounting of a substrate in a CVD reactor, which has a supporting ring that is supported by a substrate holder. The lower face of the radially inner region is supported on a supporting flank of a recess. The recess surrounds the circular disc-shaped substrate holder. The distance between the supporting flank of the recess and a lower face of the substrate holder can be greater than the distance between the lower edge of the annular web and the lower face of the radially inner region, so that the lower edge of the annular web, or an annular surface formed by the lower edge, is at a distance from a floor of a pocket, in which the substrate holder is inserted, wherein the pocket can be formed by one or a plurality of cover plates, which rest on the base body of the susceptor arrangement. A height of the annular web, which is defined by the distance of the lower edge of the annular web from the lower face of the radially inner region, can be at least 50%, or at least 80%, preferably at least 90%, but at most 100%, and preferably less than 100%, of a distance of the lower face of the substrate holder from the supporting flank. In particular, it is envisaged that gas supply lines open into the bottom of the pocket, from which a carrier gas can emerge, which gas forms a gas cushion between the bottom of the pocket and the lower face of the substrate holder, on which the substrate holder is mounted, so that the heat flow must pass through the gas cushion. The heat flow to the substrate holder can be varied with the height of the gas cushion and/or the composition of the carrier gas. The gas supply lines form nozzles that are aligned such that the gas flows emerging from the latter cause the substrate holder to rotate about an axis of rotation. Channels can be provided between the cover plates, through which gripper arms can reach; the latter can grip under the radially outer regions of the supporting ring. The susceptor arrangement can have a circular layout for this purpose. The channels extend inwards from the edge of the susceptor arrangement, wherein the channels assigned to an arrangement run parallel to each other.

The invention also relates to one or a plurality of the previously described arrangements in a CVD reactor, wherein the arrangements are arranged in a circle around a central gas inlet element. The gas inlet element can be arranged in a center of an annular process chamber. However, it is also possible for the gas inlet element to be formed by the process chamber ceiling, for example as a showerhead.

### BRIEF DESCRIPTION OF THE DRAWINGS

Example embodiments of the invention are explained in the following figures. Here:

FIG. 1 shows a perspective view of a susceptor arrangement with five substrate holders 12 annularly arranged around a center, each of which supports a substrate 10 that can be transported by means of a supporting ring 20,

FIG. 2 shows a schematic cross-section of a CVD reactor,

FIG. 3 shows a plan view onto the susceptor arrangement shown in FIG. 1,

FIG. 4 shows the detail IV in FIG. 2,

FIG. 5 shows a perspective view of a transport ring 20,

FIG. 6 shows the cross-section of the transport ring 20, and

FIG. 7 shows an illustration according to FIG. 4 of a further example of embodiment.

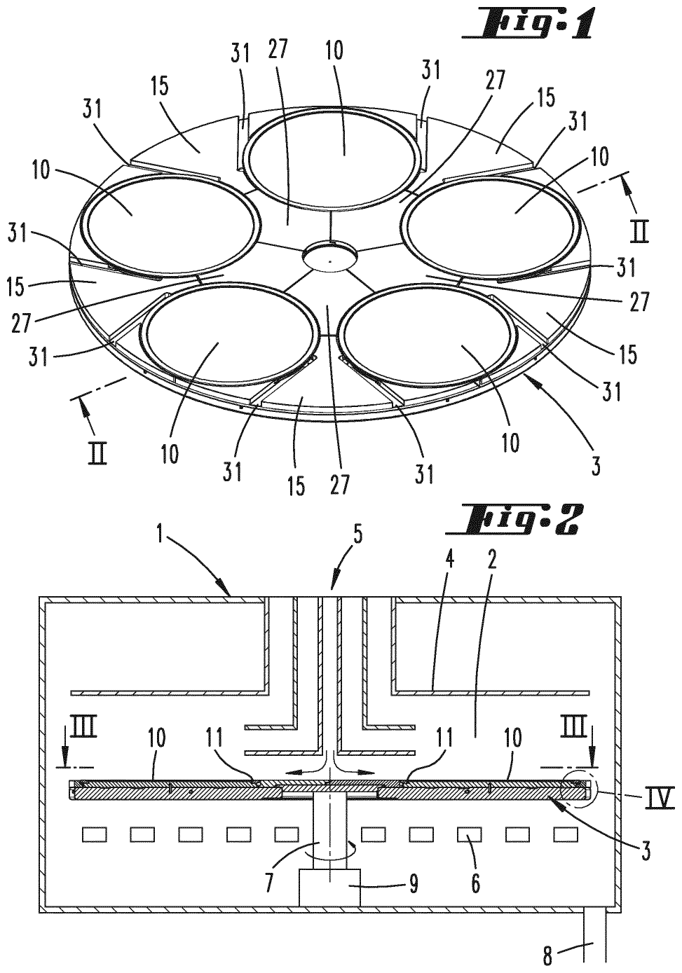

### DETAILED DESCRIPTION

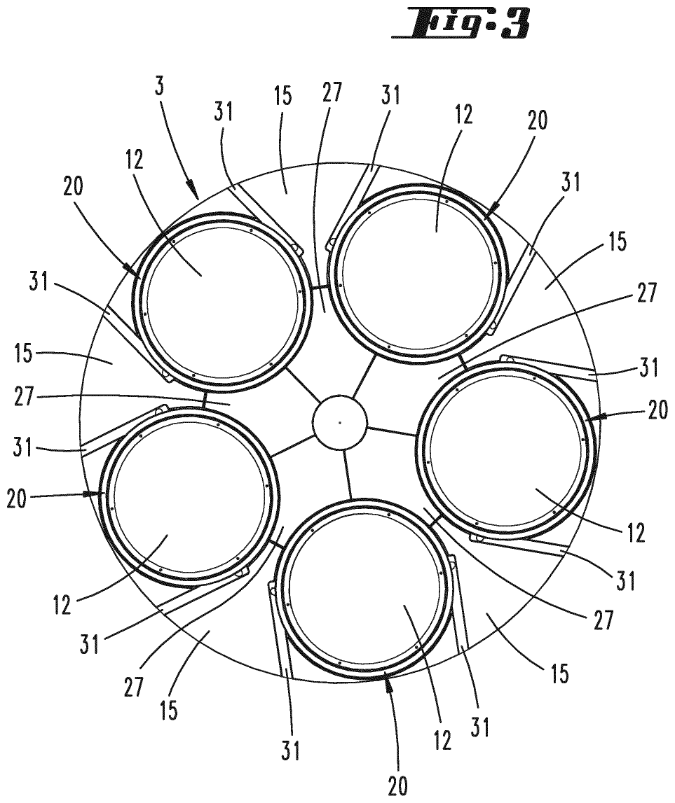

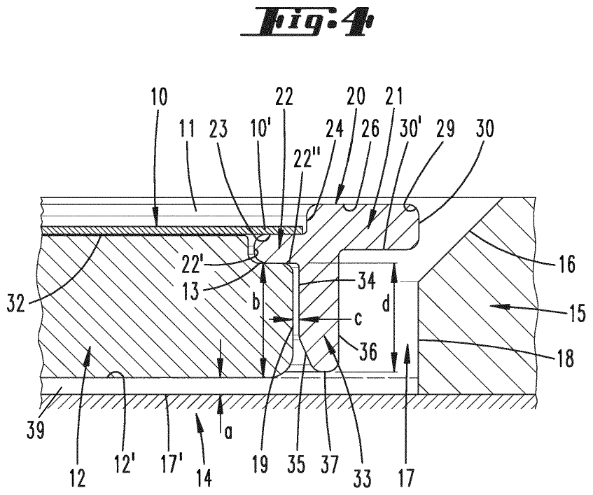

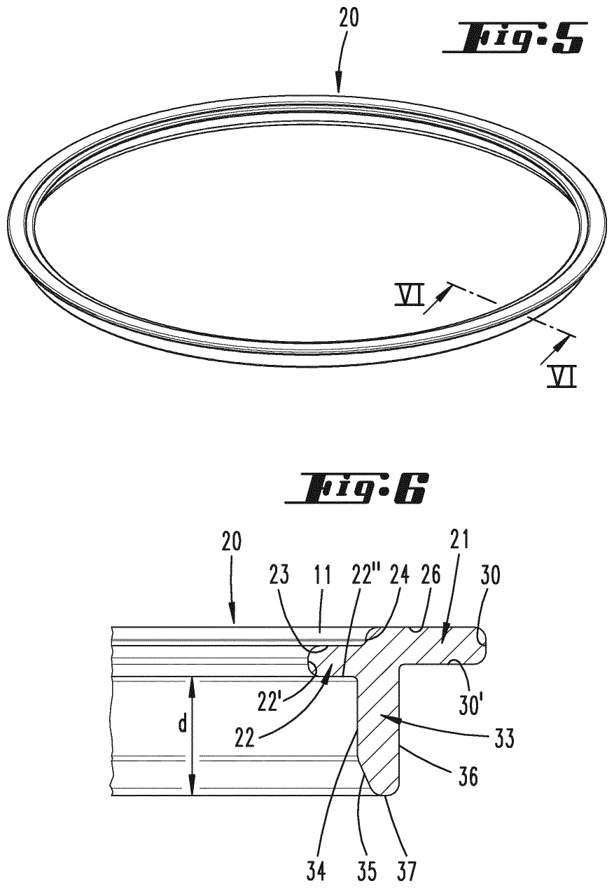

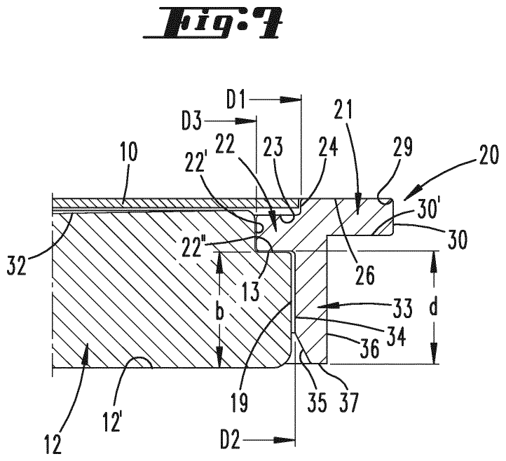

A CVD reactor, as illustrated in FIG. 2, has a stainless steel housing 1. A process chamber 2, which can be evacuated, is located inside the housing. In the example embodiment, a gas inlet element 5 is located in the center of the process chamber 2, through which various process gases can be fed into the process chamber 2. In particular, the process gases contain a gas containing the element silicon, for example silane, and a gas containing the element carbon, for example methane. These two reactive gases can be fed into the process chamber 2 with a carrier gas, for example hydrogen. The process chamber 2 is bounded at the top by a process chamber ceiling 4. The process chamber ceiling 4 can be cooled. However, it is also envisaged that the process chamber ceiling 4 may not be actively cooled. The floor of the process chamber 2 is formed by a susceptor arrangement 3, as shown in FIGS. 2 and 3.

The susceptor arrangement 3 has a base body 14 consisting of graphite, in particular coated graphite. The base body supports a number of cover plates 15, 27, which leave circular mounting spaces between them. Each of the mounting spaces forms a pocket 17, which has a floor 17′ that is formed by the base body 14.

Straight channels 31 extend in each case from the edge of the susceptor arrangement 3, which has a circular layout, approximately to the center of one of the mounting spaces. Two channels 31, which run parallel to each other, are each tangent to a mounting space. Two gripper arms of a gripper can move in through the channels 31 in order to lift a substrate 10 from the substrate holder 12.

For the deposition of SiC layers, the susceptor arrangement 3 is heated to temperatures of more than 1,000° C., and in particular to temperatures in a range above 1,300° C., and in particular in the region of 1,600° C., by means of a heating device 6 arranged below the susceptor arrangement 3. Process gases containing silicon and carbon are fed through the gas inlet element 5 into the process chamber 2, where the process gases decompose pyrolytically so that silicon carbide layers are deposited on the surface of the substrates 10 arranged there. In order to achieve a homogeneous layer thickness and, in particular, a homogeneous doping profile of the layer, the local temperature deviation of the surface temperature of the substrate 10 from a mean value must be minimal. For this purpose, it is necessary that a sufficient heat flux is also fed into the edge region of the substrate 10, and also that the heat flux fed into the edge region of the substrate 10 is not too high.

FIG. 4 shows the pocket 17, which is bounded by a cover plate 15 and has a pocket floor 17′. The edge of the pocket 17 is formed by an inner wall 18 of the cover plate 15, which runs on a hollow cylinder inner surface. Adjoined to the latter is a chamfer 16, which adjoins an upper face of the cover plate 15 facing towards the process chamber 2.

In the pocket 17 is located a circular disc-shaped substrate holder 12, which has a lower face 12′. A carrier gas is fed into the gap 39 between the lower face 12′ and the pocket base 17′ through a gas nozzle (not shown); this creates a gas cushion such that the lower face 12′ is at a distance a from the pocket floor 17′. The heat flow to the substrate 10 can be influenced by this gas cushion by using a mixture of gases with different thermal conductivities, and changing the mixing ratio, or by varying the height of the gas cushion by the rate of the gas flow.

The substrate holder 12 forms a peripheral wall 19 extending along a cylindrical shell surface, which peripheral wall adjoins a recess formed by a supporting flank 13, which extends annularly around the substrate holder 12 in a plane. The recess merges into an upper face 32 of the substrate holder 12, forming a flank that is radially offset from the peripheral wall 19. Supporting projections, on which a substrate 10 can be supported, can originate from the upper face 32. However, the upper face 32 can also have troughs.

A supporting ring 20 is provided, which has a T-shaped cross-section. The supporting ring 20 has a radially inner region 22, which has a lower face 22″, with which the radially inner region 22 can be supported on the supporting flank 13. Opposite the lower face 22′22″ is a seating face 23, which, in the operating state shown in FIG. 4, is at a distance from the edge 10′ of the substrate 10. The action of the seating face 23 evolves when the supporting ring 20 is lifted. The edge 10′ of the substrate 10 is then supported on the seating face 23. The distance of the seating face 23 from the lower face 22″ is therefore less than the height offset of the supporting flank 13 from the upper face 32 of the substrate holder.

The supporting ring 20 forms a radially outer region 21. The radially outer region has a lower face 30′, which can be gripped by one of the gripper arms so as to lift the supporting ring 20. The lower face 30′ extends in a plane that is slightly offset in height relative to the plane in which the lower face 22″ extends. The radially outer region 21 also has an upper face 26 extending in a plane that is offset in height relative to the seating face 23, such that a recess 11 is formed between the seating face 23 and a contact surface 24 surrounding the seating face 23, which extends along a hollow cylinder inner surface. The radially outer region 21 forms an outer surface 30, which lies opposite an inner surface 22′ of the radially inner region 22. The outer flank 30 can merge into the upper face 26, forming a rounding 29.

The supporting ring 20, with the radially inner region 22 and the radially outer region 21, in each case forms T-legs. With an annular web 33, the supporting ring 20 forms a T-web. The annular web 33 is a cylindrical annular body, which is moulded onto the inner region 22 and the outer region 21 in the same material. The annular web 33 has an outer wall 30, which extends along a cylindrical shell surface, and which merges into the lower face 30′, forming a right angle. An inner wall 34 of the annular web 33 adjoins the lower face 22″ of the radially inner region 22, forming a right angle. The outer wall 36 merges into a chamfer, or inclined flank, 35, forming a rounded, lower annular surface 37, which adjoins the inner wall 34 running on a hollow cylinder inner surface. The contact surface 24, against which a narrow outer edge of the substrate 10 can be supported in the course of transport or mounting, runs on a hollow cylindrical inner surface that has a radius that is slightly greater than the radius of the inner wall 34. The radius of the contact surface 24 is slightly less than the radius of the outer wall 36.

The distance between the supporting flank 13 and the lower face 12′ of the substrate holder 2, labelled b in FIG. 4, is greater than the distance d between the lower face 22″ and the lower edge, that is to say, the lower annular surface 37 of the annular web 33. The distance of the annular surface 37 from a plane passing through the lower face 12′ can be 0.5 mm to 3 mm.

The radius of the inner wall 34 is greater than the radius of the peripheral wall 19, such that a gap with the gap width c is created between the peripheral wall 19 and the inner wall 34. The distance c between the peripheral wall 19 and the inner wall 34 can be 0.5 mm to 3 mm.

The supporting ring 20 can be a homogeneous solid body made of SiC, the cross-section of which has three wings, wherein one wing is formed by the annular web 33, from which two wings formed by the inner region 22 and outer region 21 project at right angles.

The substrate 10 is heated to the process temperature by a heat flow through the substrate holder 12. The upper face of the substrate holder 12 facing towards the substrate 10 can have one or a plurality of troughs, so that the heat flow from the upper face of the substrate holder 12 to the substrate 10 takes place through a gas gap, which has locally different heights, so that the heat flow can be influenced by the profile of the floor of the trough. The upper face of the substrate holder 12 can be configured in a concave manner. Just the edge of the substrate can rest on the edge of the substrate holder 12, wherein individual support elements can here be provided to support the substrate 10. The support points or a support line, on which the substrate 10 rests, are/is distanced from the outer edge of the substrate 10. The heat flow to the edge 10′ of the substrate 10 takes place through the supporting ring 20. In the course of the coating of the substrate 10, the edge 10′ of the substrate 10 can run at a small distance above the seating face 23, so that the heat flow from the supporting ring 20 to the substrate 10 also takes place via a gas gap. In contrast to the prior art, however, the predominant heat flow from the base body 14 does not take place through the substrate holder 12 to the radially inner region 20, but rather through the annular web 33. To this end, the annular web 33 surrounds the entire substrate holder 12, so that the substrate holder 12 lies in a cavity of the supporting ring 20. The annular web 33 thus forms a heat transfer path, via which most of the heat is transferred from the base body 14 to the radially inner region 22 and/or to the radially outer region 21. The heat flow can be adjusted by way of the material thickness of the annular web 33, so that supporting rings 20 with different annular webs 33 can be used as required. The supporting ring can have a constant cross-sectional region over its entire periphery.

The gap c can have a constant gap width over preferably more than 50% of the vertical gap length, starting at the lower face 22″ up to the start of an incline 35. The incline 35 can extend along an inner region of the annular web 33, which corresponds to less than 50% of the distance d. The incline 35 can preferably merge into a rounding, which in turn can merge without an incline into the outer wall 36, so that the outer wall 36 is formed by a cylindrical shell surface that with the formation of a rounding merges into a lower annular surface 37 or ridge line. A ridge line running through the center of the lower annular surface 37 thus runs radially outwards, offset from a center line through the cross-section of the supporting ring 20. It proves to be advantageous if the radial extent of the radially outer region 21 is greater than the radial extent of the radially inner region 22. The distance of the inner surface 22′ from the inner wall 34 is thus preferably less than the distance of the outer surface 30 from the outer wall 36. It is also advantageous if the material thickness of the radially inner region 22, that is to say, the distance from the seating face 23 to the lower face 22″, is less than the material thickness of the radially outer region 21, that is to say, the distance of the upper face 26 from the lower face 30′. A further advantage of the inventive annular web 23-33 is its material thickness in the region of its root, that is to say, where the annular web 33 adjoins the lower face 22″. There, the annular web 33 has a material thickness that is less than the vertical extent of the annular web d. The material thickness of the annular web in the region of the concentrically extending cylindrical surfaces 34, 36 is preferably less than half the distance of the lower face 22″ from the lower annular surface 37. It can also be advantageous if the level of the lower face 30′ of the radially outer region 21 lies between the levels of the lower face 22″ and the upper face 23 of the radially inner region 22.

An inner wall 18 of a cover plate 15 preferably lies opposite the outer wall 36 of the annular web 33, so that the supporting ring 20 extends over a substantial region of its periphery in an annular recess, the floor of which is formed by an upper face of the base body 14, and the walls of which are formed by the peripheral wall 19 of the substrate holder 12 and the inner wall 18 of the cover plate 15.

The relatively large vertical height of the annular web 33, in combination with the radially outer region 21, has the effect of forming a stabilising body that is L-shaped in cross-section, from which a web that performs the supporting function for the substrate 10 protrudes radially inwards. The L-shaped base body means that only slight deformations of the supporting ring 10 occur during the deposition of SiC. The above-cited configuration features provide a supporting ring that is mechanically stabilized against thermal stresses compared to the prior art.

FIG. 7 shows a further example embodiment of a supporting ring 20 for carrying out a process for the deposition of SiC in a CVD reactor at temperatures higher than 1,300° C., and in particular in the region of 1,600° C. The supporting ring 20 can be made of SiC. It has a radially inner region 22, which is supported on a supporting flank 13 of a substrate holder 12, wherein the radially inner region 22 has a material thickness of approximately 2 mm and projects inwards by approximately 2 mm from an inner wall 34 of an annular web 33. The material thickness of the radially inner region 22 is less than the step height, that is to say, the distance between the upper face side 32 of the substrate holder 12 and the supporting flank 13, such that the edge of the substrate 10 is not supported on the seating face 23 when the SiC layer is deposited on the substrate 10. The seating face 23 only comes into contact with the edge of the substrate 10 when the supporting ring 20 is lifted. For this purpose, the supporting ring 20 has a radially outer region 21 which projects beyond an outer wall 36 of the annular web 33, and which has a lower face 30′ that can be gripped by a finger of a robot arm.

The radially outer region 21 forms a contact surface 24, which extends along a circular line that has a first diameter D1. The first diameter D1 is slightly greater than the diameter of the substrate 10, which is 150 mm.

The substrate holder 12 has a peripheral wall 19 extending along an arc of a circle, which has a second diameter D2 that is approximately 150 mm. As a consequence of this configuration, the substrate 10 lies centered on the substrate holder 12 during deposition of the SiC layer, wherein the edge of the substrate 10 is aligned with the cylindrical peripheral wall 19. The first diameter D1 is only greater than the second diameter D2 by the magnitude of the manufacturing tolerance on the diameter of the substrate 10. The centering function can be performed by the inner surface 22′, which can bear against an outer surface of the substrate holder 22 with little play. The third diameter D3 of this inner surface 22′ is only slightly greater than the outer diameter of the cylindrical wall of the step formed by the supporting flank 13.

The other features of the configuration correspond to the supporting ring 20 shown in FIG. 4; reference is therefore made to the statements made regarding the latter.

The above statements serve to explain the inventions covered by the application as a whole, which further the prior art at least by the following combinations of features, and also independently, wherein two, a plurality, or all of these combinations of features can also be combined, namely a CVD reactor, a supporting ring for use in a CVD reactor, and a bearing arrangement for the mounting of a substrate in a CVD reactor, in which the supporting ring is designed such that the diameter of the substrate holder essentially corresponds to the diameter of the substrate, and/or such that the radially inner region and the radially outer region of the cross-sectionally T-shaped supporting ring 20 have the same material thicknesses, and the radially inner region only extends radially inwards below the edge of the substrate over approximately the material thickness of the radially inner region 22, and/or such that the annular web 33 extends over almost the entire height of a lower section of the substrate holder 12, which is bounded at the upper face by the supporting flank 13 and at the bottom by the lower face 12′, and/or such that the substrate holder 12 lies almost completely in a cavity surrounded by the supporting ring 20, and the material is formed in one piece, wherein a maximum gap of 2 mm remains between the lower face 12′ of the substrate holder 12 and the lower annular surface 37, which is not surrounded by the supporting ring 20, and/or wherein the distances between the inner cylindrical surfaces of the supporting ring 20 and the outer cylindrical shell surfaces of the substrate holder 2 are selected such that the supporting ring 20 rests centered on a step formed by the supporting flank 13. The manufacturing tolerance of the substrate is approximately 1 mm with regard to the diameter. The manufacturing tolerance can lie between 1% and 2% of the diameter.

A CVD reactor, which is characterized by an annular web 33 that forms an inner wall 34 extending along a hollow cylindrical inner surface, which inner wall, at a distance c, extends along the peripheral wall 19.

A CVD reactor, which is characterized in that a height d of the annular web 33 measured from the bottom surface 22″ to a lower edge 37 of the annular web 33 is less than a distance b of the supporting flank 13 from the lower surface 12′ of the substrate holder 12, and/or in that the height d is less than 100% of the distance b, but is at least 50%, or at least 80%, or at least 90%, of the distance b.

A supporting ring, which is characterized in that the inner wall 34 merges into a lower annular surface 37, to which the outer wall 36 is adjoined, forming a rounding or incline 35 that reduces the material thickness of the annular web 33.

A bearing arrangement, which is characterized by an annular web 33, which forms an inner wall 34 extending along a hollow cylindrical inner surface, which inner wall, spaced at a distance c, extends along the peripheral wall 19.

A bearing arrangement, which is characterized in that a height d of the annular web 33, measured from the lower face 22″ to a lower edge 37 of the annular web 33, is less than 100%, but at least 50%, or 80%, or 95%, of a distance b of the supporting flank 13 from the lower face 12′ of the substrate holder 12.

A CVD reactor, which is characterized in that the contact surface 24, extending along a hollow cylinder inner surface, extends radially inside the outer wall 36 and radially outside the inner wall 34.

A CVD reactor, which is characterized in that the inner wall 34, with the formation of a rounding or incline 35 that reduces the material thickness of the ring 33, merges into the lower edge 37, to which the outer wall 36 is adjoined.

A CVD reactor, which is characterized in that the supporting ring 20, which is essentially D-shaped in cross-section, is made of SiC.

A CVD reactor, a bearing arrangement, or a supporting ring, which are characterized in that the radially outer region 21 forms an outer surface 30 extending along a cylindrical shell surface, and the radially inner region 22 has an inner surface 22′ extending radially inside the inner wall 34 on a hollow cylinder inner surface.

A CVD reactor, a bearing arrangement, or a supporting ring, which are characterized in that the distance between the two concentrically extending cylindrical surfaces 34, 36 is less than the distance d of the lower face 22″ of the radially inner region 22 from the lower surface 37 of the annular web 33, and is at most 50% of the distance d.

A CVD reactor, a bearing arrangement, or a supporting ring, which are characterized in that the inner cylindrical surface 34 has a greater height than the outer cylindrical surface 36.

All the disclosed features are (individually, but also in combination with each other) essential to the invention. The disclosure of the application hereby also includes the disclosure content of the associated/attached priority documents (copy of the prior application), also for the purpose of including features of these documents in the claims of the present application, With their features the subsidiary claims characterise, even without the features of a referenced claim, independent inventive developments of the prior art, in particular in order to make divisional applications on the basis of these claims. The invention specified in each claim can additionally have one or a plurality of the features specified in the above description, in particular those provided with reference numerals, and/or specified in the list of reference numerals. The invention also relates to configurational forms in which individual features cited in the above description are not implemented, in particular insofar as they are recognisably dispensable for the intended use in question, or can be replaced by other technically equivalent means.

### LIST OF REFERENCE SYMBOLS

1 CVD reactor housing
2 Process chamber
3 Susceptor arrangement
4 Process chamber ceiling
5 Gas inlet
6 Heating device
7 Shaft
8 Gas outlet device
9 Rotary drive
10 Substrate
10′ Edge of the substrate
11 Recess
12 Substrate holder
12′ Lower face
13 Supporting flank
14 Base body
15 Cover plate
16 Chamfer
17 Pocket
17 Pocket floor
18 Inner wall
19 Perimeter wall
20 Supporting ring
21 Radial outer region
22 Radial inner region
22′ Inner surface
22″ Lower face
23 Seating face
24 Contact surface
25 Rounded edge
26 Upper face
27 Cover plate
29 Rounded edge
30 Outer surface
30′ Lower face
31 Channel
32 Upper face
33 Annular web
34 Inner wall
35 Incline
36 Outer wall
37 Lower annular surface
39 Gap
a Gap height
b Distance
c Gap width
d Distance
D1 First diameter
D2 Second diameter
D3 Third diameter

1. A chemical vapor deposition (CVD) reactor for the deposition of an SiC layer on a substrate (10), the CVD reactor comprising:
a housing (1);
a susceptor arrangement (3) arranged within the housing (1);
a heating device (6) for the heating of the susceptor arrangement (3);
a process chamber ceiling (4);
a process chamber (2) arranged between the process chamber ceiling (4) and the susceptor arrangement (3); and
a gas inlet element (5) for the feeding of a process gas into the process chamber (2), wherein the susceptor arrangement (3) comprises:
a bearing device for mounting a substrate (10) to be treated in the process chamber (2);
a circular disc-shaped substrate holder (12) having a first upper face (32), and a first lower face (12′) located opposite to the first upper face (32);
a peripheral wall (19) extending along a first cylindrical surface;
a supporting ring (20) carried by a supporting flank (13) of the substrate holder (12), wherein the supporting ring (20) has a radially inner region (22) with a second lower face (22″) that rests on the supporting flank (13), and a second upper face located opposite the second lower face (22″) that forms a seating face (23) for seating an edge (10′) of the substrate (10), wherein the supporting ring (20) has a radially outer region (21) with a third upper face (26) and a third lower face (30′) located opposite the third upper face (26), the third lower face (30′) adjoining an outer wall (36) extending along a second cylindrical surface, and wherein the seating face (23) is bounded by a contact surface (24) with a first diameter (D1); and
an annular web (33) with an inner wall (34) extending along a third cylindrical surface with a second diameter (D2), wherein the annular web (33) extends along the peripheral wall (19), wherein the first diameter (D1) is greater than the second diameter (D2) only by a magnitude of a diametric tolerance of the substrate (10), and wherein a height (d) of the annular web (33) measured between the second lower face (22″) of the radially inner region (22) and a lower edge (37) of the annular web (33) is less than a distance (b) between the supporting flank (13) and the first lower face (12′).

2. The CVD reactor of claim 1, wherein the height (d) is at least 50% of the distance (b).

3. A supporting ring (20) for use in a chemical vapor deposition (CVD) reactor for depositing a SiC layer on a substrate (10), the supporting ring (20) comprising:
a radially inner region (22) with a first lower face (22″) configured to rest on a supporting flank (13) of a substrate holder (12), and a first upper face that forms a seating face (23) located opposite the first lower face (22″), the seating face (23) being adjoined by a contact surface (24) with a first diameter (D1);
a radially outer region (21) with a second upper face (26) and a second lower face (30′) that is located opposite the second upper face (26); and
an annular web (33) with an outer wall (36) extending along a first cylindrical surface and an inner wall (34) located opposite the outer wall (36), wherein the second lower face (30′) adjoins the outer wall (36) of the annular web (33), wherein the inner wall (34) extends along a second cylindrical surface and adjoins the first lower face (22″) of the radially inner region (22), wherein the first lower face (22″) of the radially inner region (22) extends radially within the inner wall (34) of the annular web (33), and wherein the first diameter (D1) is only larger than a second diameter (D2) of the inner wall (34) by a magnitude of a diametric tolerance of the substrate (10).

4. A bearing arrangement for mounting a substrate (10) in a chemical vapor deposition (CVD) reactor, the bearing arrangement comprising:
a substrate holder (12) with a peripheral wall (19) extending along a first cylindrical surface, and with a supporting flank (13); and
a supporting ring (20) supported by the supporting flank (13) of the substrate holder (12),
wherein the supporting ring (20) comprises:
a radially inner region (22) with a first lower face (22″) that rests on the supporting flank (13), and a first upper face located opposite the first lower face (22″), the first upper face forming a seating face (23) for seating of an edge (10′) of the substrate (10), wherein the seating face (23) is bounded by a contact surface (24) with a first diameter (D1);
a radially outer region (21) with a second upper face (26) and a second lower face (30′) located opposite the second upper face (26); and
an annular web (33) with an outer wall (36) extending along a second cylindrical surface and an inner wall (34) extending along a third cylindrical surface, the inner wall (34) having a second diameter (D2), wherein the first diameter (D1) is only larger than the second diameter (D2) by a magnitude of a diametric tolerance of the substrate (10).

5. The bearing arrangement of claim 4, wherein a height (d) of the annular web (33), measured from the first lower face (22″) of the radially inner region (22) to a lower edge (37) of the annular web (33), is less than 100%, but is at least 50% of a distance (b) between of the supporting flank (13) and the first lower face (12′) of the substrate holder (12).

6. The supporting ring (20) of claim 3, wherein the contact surface (23) extending along a third cylindrical surface extends radially inside the outer wall (36), and radially outside the inner wall (34).

7. The supporting ring (20) of claim 3, wherein the inner wall (34), with a rounding or inclined flank (35) that reduces a material thickness of the annular web (33), merges into a lower edge (37) of the annular web (33), and wherein the lower edge (37) of the annular web (33) adjoins the outer wall (36).

8. The supporting ring (20) of claim 3, wherein the supporting ring (20), which is essentially T-shaped in cross-section, is made of SiC.

9. The supporting ring (20) of claim 3, wherein the radially outer region (21) forms an outer surface (30) extending along a third cylindrical surface, and the radially inner region (22) has an inner surface (22′) extending radially inside the inner wall (34) along a fourth cylindrical surface.

10. The supporting ring (20) of claim 3, wherein the first cylindrical surface is concentric with the second cylindrical surface, wherein a distance between the first and second cylindrical surfaces is at most 50% of a height (d) between the first lower face (22″) of the radially inner region (22) and a lower surface (37) of the annular web (33).

11. The supporting ring (20) of claim 3, wherein the inner wall (34) has a greater height than the outer wall (36).

12. The supporting ring (20) of claim 3, wherein a distance between the first lower face (22″) and the seating face (23) of the radially inner region (22) is less than a distance between the supporting flank (13) and a third upper face (32) of the substrate holder (12).

13. The supporting ring (20) of claim 3, wherein at least one of:
(i) a material thickness of the radially inner region (22) corresponds to a material thickness of the radially outer region (21), or
(ii) the material thickness of the inner region (22) and the material thickness of the outer region (21) are each 2 mm.

14. The supporting ring (20) of claim 3, wherein a distance between the inner wall (34) and the outer wall (36), which defines a material thickness of the annular web (33), is less than half a distance (d) between the first lower face (22″) and a lower edge (37) of the annular web (33).

15. (canceled)

16. The CVD reactor of claim 1, wherein the contact surface (23) extends along a fourth cylindrical surface, extends radially inside the outer wall (36), and radially outside the inner wall (34).

17. The CVD reactor of claim 1, wherein the inner wall (34), with a rounding or inclined flank (35) that reduces a material thickness of the annular web (33), merges into the lower edge (37), and wherein the lower edge (37) adjoins the outer wall (36).

18. The CVD reactor of claim 1, wherein the supporting ring (20), which is essentially T-shaped in cross-section, is made of SiC.

19. The CVD reactor of claim 1, wherein the radially outer region (21) forms an outer surface (30) extending along a fourth cylindrical surface, and the radially inner region (22) has an inner surface (22′) extending radially inside the inner wall (34) along a fifth cylindrical surface.

20. The CVD reactor of claim 1, wherein the second cylindrical surface is concentric with the third cylindrical surface, wherein a distance between the second and third cylindrical surfaces is at most 50% of the height (d) of the annular web (33) between the first lower face (22″) of the radially inner region (22) and the lower surface (37) of the annular web (33).

21. The CVD reactor of claim 1, wherein the inner wall (34) has a greater height than the outer wall (36).
